(19) United States
(12) Patent Application Publication
(10) Pub. No.: US 2013/0293245 A1
(43) Pub. Date: Nov. 7, 2013

(54) SENSOR UNIT FOR REMOTELY ACTUATING A VEHICLE DOOR, VEHICLE DOOR HAVING THE SENSOR UNIT AND METHOD OF PRODUCING THE SENSOR UNIT

(71) Applicant: BROSE FAHRZEUGTEILE GMBH & CO. KG, HALLSTADT, HALLSTADT (DE)

(72) Inventors: THORSTEN KUHNEN, LITZENDORF (DE); ANDRE GUNREBEN, HALLSTADT (DE); HOLGER WUERSTLEIN, ZEIL AM MAIN (DE)

(21) Appl. No.: 13/939,637

(22) Filed: Jul. 11, 2013

Related U.S. Application Data
(63) Continuation of application No. PCT/EP2011/006570, filed on Dec. 24, 2011.

(30) Foreign Application Priority Data
Jan. 11, 2011 (DE) 102011008275.1

(51) Int. Cl. G01R 27/26; B60J 5/10; H01R 43/20

(52) U.S. Cl. CPC G01R 27/2605; H01R 43/20; B60J 5/107
USPC 324/658; 29/876; 296/146.1; 296/146.8

(57) ABSTRACT

A capacitive sensor unit is not susceptible to failure and remotely actuates a door of a vehicle. The sensor unit contains an electrode assembly having an elongated sensor electrode and a supply line for electrically connecting the sensor electrode to an evaluation unit. The supply line is surrounded by a shield. An additional ground conductor, which is electrically conductively connected to the shield over the entire length of the supply line, is connected in parallel to the supply line.

### CROSS-REFERENCE TO RELATED APPLICATION

This is a continuation application, under 35 U.S.C. §120, of copending international application No. PCT/EP2011/006570, filed Dec. 24, 2011, which designated the United States; this application also claims the priority, under 35 U.S.C. §119, of German patent application No. DE 10 2011 008 275.1, filed Jan. 11, 2011; the prior applications are herewith incorporated by reference in their entirety.

### BACKGROUND OF THE INVENTION

### Field of the Invention

The invention relates to a sensor unit for contactlessly actuating, that is to say for opening or closing, a vehicle door, in particular a tailgate.

For a user of a vehicle, it is desirable, under certain circumstances, to contactlessly open or close a vehicle door, in particular the tailgate of a trunk. This need occurs, in particular, when the vehicle is being loaded or unloaded and the user uses both hands to carry an object, for example a case of beer.

Currently under development are sensor units having proximity sensors which are arranged in the rear area of a vehicle and can detect, for example, a foot movement of a vehicle user as a door opening signal. As a result, an evaluation unit which is coupled to the proximity sensors in terms of signaling can output a triggering signal for automatically actuating the tailgate.

Similar sensor units are furthermore also situated in apparatuses for contactless trapping protection in electrical actuators, for example an electric window regulator. In this case, the sensor unit is used to detect a body part of a vehicle user or another object in the travel of the vehicle part to be adjusted and to stop or reverse the adjustment of the vehicle part before the body part or the object is trapped.

In this case, conventional proximity sensors are often in the form of capacitive sensors. In the case of such sensors, there is the problem that the electrical supply lines between the or each sensor electrode and the evaluation unit of such a sensor can themselves act as an additional active sensor surface. In this case, the parasitic capacitances caused by the supply lines may disrupt and/or distort the measurement result of such a sensor. This is particularly critical for the contactless actuation of a vehicle door, in particular, especially since a particular movement of a vehicle user is often intended to be selectively identified as a door opening wish in this case, while the door is intended to remain closed when a vehicle user approaches in another manner. Influencing of the measurement signal by parasitic capacitances often results, in conventional sensor units, in high error rates when identifying a door opening wish. Such interfering effects have a greater effect with increasing length of the supply line.

Published, non-prosecuted German patent application DE 102 26 133 A1, corresponding to U.S. Pat. No. 6,936,986, discloses a sensor unit for a contactlessly operating an anti-trapping apparatus. In this case, the sensor unit contains a capacitive sensor electrode which is connected to an evaluation unit by a shielded conductor.

### BRIEF SUMMARY OF THE INVENTION

The invention is based on the object of specifying a sensor unit, which is particularly unsusceptible to errors and is intended to contactlessly actuate a vehicle door, and a vehicle having such a sensor unit. The invention is also based on the object of specifying a particularly suitable method for producing such a sensor unit.

The sensor unit according to the invention contains an elongated sensor electrode. The sensor unit also contains a supply line for electrically connecting the sensor electrode to an evaluation unit, the supply line being surrounded by an electrical shield. The assembly formed from the sensor electrode and the shielded supply line is referred to as the “electrode assembly” below. The electrode assembly additionally contains a ground conductor (or grounding conductor) which is routed parallel to the supply line and is connected to the shield in an electrically conductive manner over the entire length of the supply line.

During operation of the sensor unit, the shield is used as a Faraday cage to shield from external electromagnetic interference fields and capacitive interfering influences from other electrical devices. Interfering influences on the measurement signal from the sensor electrode are thus reduced, as a result of which the evaluation unit can detect capacitive changes in the electric field of the sensor electrode—at least largely—in an undistorted manner. The supply line which has only a merely length-dependent capacitance as a result of the shield has a constant influence on the electric field produced by the sensor electrode. This readily makes it possible to compensate for the influence of the shielded supply line on the measurement signal in terms of circuitry or programming by the evaluation unit. The shield therefore makes it possible to configure the supply line to be particularly long without critically reducing the measurement accuracy. This in turn makes it possible to arrange the evaluation unit largely independently of the sensor electrode in spatial terms. In particular, the evaluation unit can thus be placed, in one preferred embodiment of the invention, in the dry compartment of a vehicle body which is sealed with respect to the outside and is therefore weatherproof.

The ground conductor routed parallel to the supply line, on the one hand, improves the stability and mechanical load-bearing capacity of the electrode assembly. On the other hand, the shield is bridged in a low-impedance manner along its entire length by the ground conductor. This significantly reduces the likelihood of any damage to the shield resulting in impairment of the shielding effect. The load-bearing capacity of the shield itself is therefore subject to only comparatively low requirements. In particular, in one preferred embodiment, this makes it possible to produce the shield in the form of a winding from a thin metal foil, without this being at the expense of the fail safety.

In an expedient embodiment, the ground conductor is enclosed by an electrically conductive covering sheath in a fluid-tight manner, in particular in a watertight manner. The ground conductor is directly and particularly effectively protected by the covering sheath from weather influences and corrosion caused thereby. The covering sheath may be provided as the only weather protection for the ground conductor. In particular, an outer sheath jointly surrounding the supply line and the ground conductor may therefore be optionally omitted. However, such an outer sheath is preferably provided as additional or alternative protection against water and dirt. For reasons of simple producibility, the outer sheath is formed, in an expedient embodiment, by a winding made of a plastic film, in particular an adhesive insulating tape. In order to avoid dirt and water penetrating at the ends of the supply line and the sensor electrode and therefore to likewise improve the unsusceptibility of the electrode assembly to corrosion, one or more seals are expediently additionally fitted at the free end of the sensor electrode and/or at the junction between the sensor electrode and the supply line. The seals are expediently produced by injection-molding with a thermoplastic material or by potting with an epoxy resin or the like.

In one particularly suitable refinement, the covering sheath is formed from an electrically conductive plastic, in particular an intrinsically conductive polymer, for example polyaniline. In this embodiment, the covering sheath not only provides particularly effective corrosion protection for the ground conductor. Rather, the covering sheath also ensures particularly good two-dimensional bearing of the ground conductor on the shield.

In principle, the ground conductor may be arranged outside the shield. However, it preferably runs, together with the supply line, inside the shield.

The electrode assembly is advantageously produced with a plug, with the result that contact can be made with the sensor unit via a plug connection to the evaluation unit. This embodiment makes it possible to mount the sensor unit in a simple and practical manner.

Both the supply line and the ground conductor are preferably in the form of stranded conductors. In an advantageous embodiment, the sensor electrode and the supply line are formed in one piece with one another, that is to say form length sections of a single uninterrupted line.

In the preferred application, the vehicle door to be actuated is a tailgate. For this purpose, the sensor unit is expediently arranged in the rear bumper of a vehicle in its intended installation situation. However, it is also conceivable to use the sensor unit to actuate other vehicle doors, for example a sliding door moved by motor. In this case, the sensor electrode is expediently arranged on the vehicle in the vicinity of this door in the intended installation position.

In the sense of particularly efficient production of the electrode assembly described above, use is preferably made of an originating line which contains, over its entire length, a first conductor, a shield surrounding the latter, a filler braided wire running inside or outside the shield and an insulating outer sheath, in particular an extruded outer sheath, which encases these parts. In this case, both the supply line and the sensor electrode are formed from the first conductor by virtue of the outer sheath, the shield and the filler braided wire being removed in a length area corresponding to the subsequent sensor electrode, with the result that the first conductor protrudes beyond the shield and the filler braided wire in this length area in order to form the sensor electrode. The ground conductor is formed by the filler braided wire in the electrode assembly produced in this manner.

In an equally preferred alternative method, the electrode assembly is assembled, as it were, from its individual components by virtue of a first conductor used as the supply line, a sensor electrode and a second conductor used as the ground conductor being covered with a metal foil used as the shield in a length area forming the subsequent supply line, and in which the shield is then covered with a plastic film used as the outer sheath, in particular an adhesive insulating tape.

Other features which are considered as characteristic for the invention are set forth in the appended claims.

Although the invention is illustrated and described herein as embodied in a sensor unit for remotely actuating a vehicle door, a vehicle door having the senor unit and method of producing the sensor unit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 shows a schematic illustration of a sensor unit for contactlessly actuating a tailgate of a vehicle, having an electrode assembly containing a sensor electrode and a shielded supply line according to the invention; and

FIG. 2 is diagrammatic, sectional view of the shielded supply line taken along line II-II shown in FIG. 1.

### DESCRIPTION OF THE INVENTION

Mutually corresponding parts and variables are always provided with the same reference symbols in all figures.

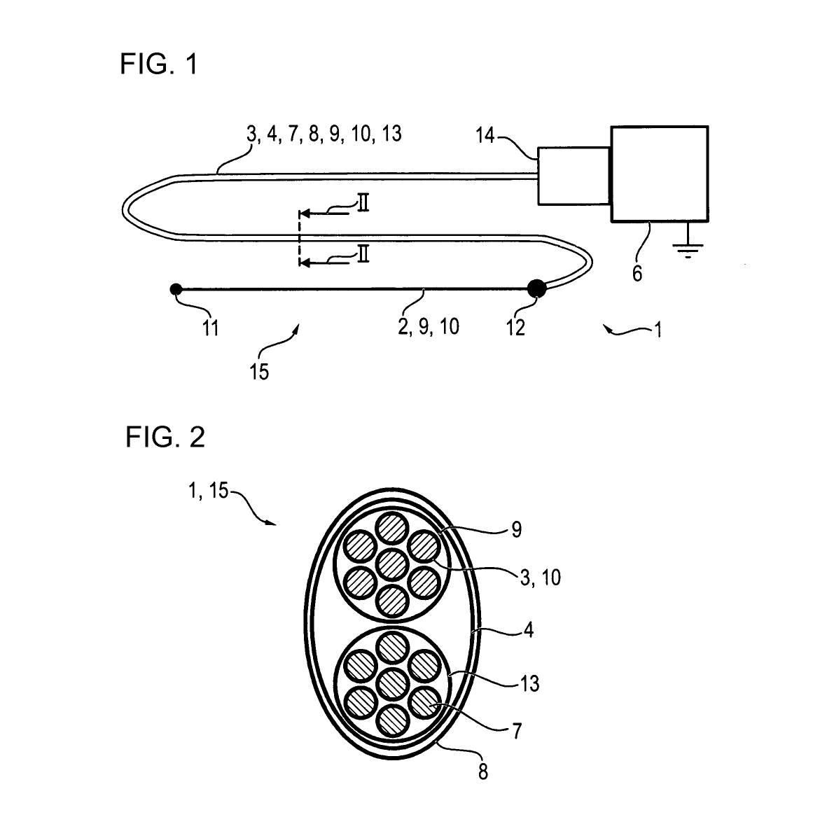

Referring now to the figures of the drawing in detail and first, particularly, to FIGS. 1 and 2 thereof, there is shown a sensor unit 1 containing an elongated sensor electrode 2 and an electrical supply line 3, the supply line 3 being surrounded by an electrical shield 4. The supply line 3 connects the sensor electrode 2, in terms of signaling, to an evaluation unit 6 which, in a preferred embodiment, is at least substantially formed by a microcontroller with control and evaluation software implemented thereon. The evaluation unit 6 is also used to connect the shield 4 to a ground potential.

As can be seen, in particular, from FIG. 2, an additional ground conductor 7 is connected in parallel with the supply line 3, is connected to the shield 4 in an electrically conductive manner over the entire length of the supply line 3 and with which contact is likewise made at ground by the evaluation unit 6.

The ground conductor 7 is arranged, together with the supply line 3, inside the shield 4. The shield 4 is in turn encased by an insulating outer sheath 8 on the outside.

The supply line 3 is a stranded conductor 10 surrounded with an insulation 9. The sensor electrode 2 is formed in one piece with the supply line 3. The sensor electrode 2 and the supply line 3 are therefore formed by the same uninterrupted stranded conductor 10. As can be gathered from FIG. 1, the shield 4 and the ground conductor 7 and also the outer sheath 8 extend solely over that length area of the stranded conductor 10 which forms the supply line 3. In contrast, in the length area forming the sensor electrode 2, the stranded conductor 10 freely projects, together with the insulation 9 surrounding the latter, from the shield 4 and the outer sheath 8 surrounding the latter.

At its free end, the sensor electrode 2 is sealed in a watertight manner by a seal 11. A further seal 12 is arranged at the attachment of the shield 4 and the outer sheath 8, which is to say at the junction between the sensor electrode 2 and the supply line 3. The seals 11 and 12 are produced, in particular, by injection-molding the stranded conductor 10 and the outer sheath 8 with a thermoplastic material at the end.

In the exemplary embodiment illustrated in FIGS. 1 and 2, the ground conductor 7 is embedded in a covering sheath 13 made of an electrically intrinsically conductive plastic, for example polyaniline, which encloses the ground conductor 7 in a watertight manner but nevertheless allows two-dimensional electrical contact between the ground conductor 7 and the shield 4. In this exemplary embodiment, the shield 4 contains a metal foil wound around the supply line 3 and the ground conductor 7.

In this exemplary embodiment, the outer sheath 8 is also wound and contains an insulating plastic film, in particular an adhesive insulating tape. In this case, the shield 4 and the outer sheath 8 are expediently wound in opposite directions, with the result that the individual film webs of the shield 4 and of the outer sheath 8 cross one another.

The supply line 2 and the ground conductor 7 are produced, on the end facing the evaluation unit 6, with a common electrical plug connector 14 with which contact can be reversibly made with a corresponding electrical mating plug connector of the evaluation unit 6.

The assembly formed from the stranded conductor 10 with the insulation 9 surrounding the latter, the ground conductor 7 with the covering sheath 13 surrounding the latter, the shield 4, the outer sheath 8, the seals 11 and 12 and the plug connector 14 is also referred to, in summary, as the electrode assembly 15.

In order to produce the above-described embodiment of the electrode assembly 15, the stranded conductor 10 surrounded with the insulation 9 and the ground conductor 10 surrounded with the covering sheath 13 are cut to the respectively desired length and are together covered with the metal foil forming the shield 4. In a subsequent method step, the shield 4 produced in this manner is in turn covered with the plastic film forming the outer sheath 8. The seals 11 and 12 and the plug connector 14 are then attached.

In a further embodiment (not illustrated in any more detail) of the electrode assembly 15, the covering sheath 13 is missing. In this case, the ground conductor 7 is rather formed by a blank filler braided wire which can be arranged either inside or outside the shield 4. In this embodiment, the shield 4 can also be formed by a wound metal foil. Alternatively, however, the shield 4 is formed from a wire mesh here. In this embodiment, the outer sheath 8 is formed from an extruded plastic material.

In order to produce this further embodiment of the electrode assembly 15, use is made of an originating line in which the stranded conductor 10 which is again insulated is first of all flanked, over its entire length, by the ground conductor 7, the shield 4 and the outer sheath 8. In this case, the outer sheath 8, the shield 6 and the ground conductor 7 are removed in that length area of the stranded conductor 10 which is intended to form the sensor electrode 2. The seals 11 and 12 and the plug connector 14 are then again attached.

The sensor unit 1 is preferably used to contactlessly identify a vehicle user's wish to open the tailgate and to automatically open the tailgate as soon as such a tailgate opening wish is identified by the sensor unit 1. In this case, the tailgate opening wish to be identified is supposed to be signaled by the vehicle user, for example, by virtue of the vehicle user briefly holding a leg—in particular in the form of a kicking movement—below the rear bumper of the vehicle.

In order to detect the approach of the leg, the electrode assembly 15 of the sensor unit 1 is expediently arranged, in the intended final assembly state thereof, in or on the rear bumper of the vehicle. For reliable and specific identification of the tailgate opening wish, the sensor unit 1 optionally contains a plurality of electrode assemblies 15 which are connected together with the sensor unit 1 and are arranged, for example, at different heights on or in the bumper.

In contrast, the evaluation unit 6 is preferably arranged in the dry compartment of the vehicle body in a weatherproof manner.

During operation of the sensor unit 1, the evaluation unit 6 applies an electrical AC voltage to the supply line 3 of the or each electrode assembly 15, under the action of which voltage an electrical alternating field is produced in a spatial region (detection area) which surrounds the sensor electrode 2 of the respective electrode assembly 15.

The vehicle user's leg in the detection area acts as a counter-electrode to the sensor electrode 2 on account of the electrical conductivity of the human body tissue and the grounding of the body tissue with the subsoil. The sensor electrode 2 thus forms, with the body part, an (electrical) capacitor, the capacitance of which characteristically changes with the distance between the body part and the respective sensor electrode 2.

In order to identify a tailgate opening wish, the evaluation unit 6 records the electrical voltage applied to the or each sensor electrode 2 and the current respectively flowing across the or each sensor electrode 2. The evaluation unit 6 uses these current and voltage values to calculate a measure of capacitance which is formed between the respective sensor electrode 2 and ground and is either the capacitance itself or a measurement variable correlated therewith. The measure of capacitance is compared by the evaluation unit 6 with a stored triggering criterion, the evaluation unit 6 outputting a triggering signal, which causes the tailgate to be opened, to an actuating drive of the tailgate as soon as the or each measure of capacitance satisfies the associated triggering criterion. For example, the evaluation unit 6 outputs the triggering signal when the capacitances respectively recorded for two electrode assemblies 15 simultaneously exceed a respectively associated threshold value for a period of more than one second and less than five seconds.

1. A capacitive sensor unit for contactlessly actuating a vehicle door of a vehicle, the capacitive sensor unit comprising:
an evaluation unit; and
an electrode assembly having a shield, an elongated sensor electrode and a supply line for electrically connecting said elongated sensor electrode to said evaluation unit, said supply line being surrounded by said shield, said electrode assembly further having a ground conductor connected in parallel with said supply line and connected to said shield in an electrically conductive manner over an entire length of said supply line.

2. The sensor unit according to claim 1, wherein said electrode assembly further comprising an electrically conductive covering sheath enclosing said ground conductor in a fluid-tight manner.

3. The sensor unit according to claim 2, wherein said electrically conductive covering sheath is formed from an electrically conductive plastic.

4. The sensor unit according to claim 1, wherein said elongated sensor electrode is formed in one piece with said supply line being an electrical supply line.

5. The sensor unit according to claim 1, wherein said electrode assembly further comprises an electrically insulating outer sheath enclosing said shield, said electrically insulating outer sheath being in a form of a winding.

6. The sensor unit according to claim 1, wherein said electrode assembly further comprises an electrically conductive covering sheath enclosing said ground conductor in a watertight manner.

7. The sensor unit according to claim 2, wherein said electrically conductive covering sheath is formed from an intrinsically conductive polymer.

8. A vehicle, comprising:
a vehicle door; and
a sensor unit contactlessly actuating said vehicle door, said sensor unit containing an evaluation unit and an electrode assembly having a shield, an elongated sensor electrode and a supply line for electrically connecting said elongated sensor electrode to said evaluation unit, said supply line being surrounded by said shield, said electrode assembly further having a ground conductor connected in parallel with said supply line and connected to said shield in an electrically conductive manner over an entire length of said supply line.

9. The vehicle according to claim 8, further comprising a motor vehicle bumper on or in which said elongated sensor electrode of said sensor unit is disposed.

10. The vehicle according to claim 6, further comprising a vehicle body, said evaluation unit of said sensor unit disposed in a dry compartment of said vehicle body which is sealed with respect to an outside.

11. The vehicle according to claim 8, wherein:
the vehicle is a motor vehicle; and
said vehicle door is a tailgate.

12. A method for producing an electrode assembly for a sensor unit, the electrode assembly having a shield, an elongated sensor electrode and a supply line for electrically connecting the elongated sensor electrode to an evaluation unit, the supply line being surrounded by the shield, the electrode assembly further having a ground conductor connected in parallel with the supply line and connected to the shield in an electrically conductive manner over an entire length of the supply line, which comprises the steps of:
providing an originating line containing over an entire length:
a first conductor forming the supply line and the elongated sensor electrode;
the shield surrounding the first conductor;
a filler braided wire forming the ground conductor;
an insulating outer sheath encasing the first conductor, the shield, and the ground conductor; and
removing the insulating outer sheath, the shield and the filler braided wire in a length area corresponding to the elongated sensor electrode.

13. A method for producing an electrode assembly for a sensor unit, the electrode assembly having a shield, an elongated sensor electrode and a supply line for electrically connecting the elongated sensor electrode to an evaluation unit, the supply line being surrounded by the shield, the electrode assembly further having a ground conductor connected in parallel with the supply line and connected to the shield in an electrically conductive manner over an entire length of the supply line, which comprises the steps of:
providing a first conductor forming the supply line and the elongated sensor electrode;
providing a second conductor forming the ground conductor;
covering the first and second conductors with a metal foil forming the shield in a length area forming the supply line; and
covering the shield with a plastic film forming an outer sheath.
